(19) United States
(12) Patent Application Publication
(10) Pub. No.: US 2015/0131248 A1
(43) Pub. Date: May 14, 2015

(54) THREE-DIMENSIONAL MODULES FOR ELECTRONIC INTEGRATION

(71) Applicant: Eagantu Ltd., Ra'anana (IL)

(72) Inventors: Michael Dakhiya, Tel Aviv (IL); Eran Shaked, Ra'anana (IL)

(21) Appl. No.: 14/397,903

(22) PCT Filed: May 9, 2013
(86) PCT No.: PCT/IB2013/053749

§ 371 Date: Oct. 30, 2014

Related U.S. Application Data
(60) Provisional application No. 61/648,098, filed on May 17, 2012.
(60) Provisional application No. 61/654,888, filed on Jun. 3, 2012.
(60) Provisional application No. 61/670,616, filed on Jul. 12, 2012.

(51) Int. Cl. H05K 1/02; H05K 3/36; H05K 3/30; H05K 1/18; H05K 1/14

(52) U.S. Cl. CPC H05K 1/0284; H05K 1/183; H05K 1/144; H05K 3/306; H05K 3/36
USPC 361/761; 174/255; 29/837; 29/830

(57) ABSTRACT

An electronic module (20, 39, 60, 80, 132, 140, 144) includes a substrate (21), which includes a dielectric material having a cavity (40, 42, 134, 142) formed therein. First conductive contacts (44) within the cavity are configured for contact with at least one first electronic component (32) that is mounted in the cavity. Second conductive contacts (44) on a surface of the substrate that surrounds the cavity are configured for contact with at least a second electronic component (28, 30) that is mounted over the cavity. Conductive traces (36, 48) within the substrate are in electrical communication with the first and second conductive contacts.

### CROSS-REFERENCE TO RELATED APPLICATIONS

This application claims the benefit of U.S. Provisional Patent Application 61/648,098, filed May 17, 2012; U.S. Provisional Patent Application 61/654,888, filed Jun. 3, 2012; and U.S. Provisional Patent Application 61/670,616, filed Jul. 12, 2012. All of these provisional patent applications are incorporated herein by reference.

### FIELD OF THE INVENTION

The present invention relates generally to electronic circuits and systems, and particularly to assembly of integrated circuits and other components in such circuits and systems.

### BACKGROUND

Modern electronic devices contain ever larger numbers of components and increasing degrees of complexity. At the same time, designers are required to fit these components into ever smaller end-products.

These conflicting demands have led to the development of highly-integrated approaches to chip design and packaging. For example, multi-chip modules (MCMs) typically contain multiple integrated circuits (ICs) or semiconductor dies, and possibly discrete components, as well, on a unifying substrate. The MCM can then be assembled as a single component onto a printed circuit board. Some advanced MCMs use a “chip-stack” package, in which semiconductor dies are stacked in a vertical configuration, thus reducing the size of the MCM footprint (at the expense of increased height). Some designs of this sort are also referred to as a “system in package.”

As an example of this sort of design, U.S. Pat. No. 5,905,635 describes an assembly of electronic modules with a support structure. Each electronic module is in the form of electronic components stacked on at least two levels, which are separated by an intermediate layer. Each electronic module comprises at least one hole formed in the intermediate layer, while the support structure comprises at least one rod element that is introduced into respective holes of successive modules.

Although IC chips are usually mounted on the surface of an MCM or printed circuit substrate, in some designs an IC may be mounted in a recess in the substrate. For example, U.S. Pat. No. 7,116,557 describes an imbedded component integrated circuit assembly, in which IC components are imbedded within a laminate substrate disposed on a thermally conductive core, which provides a thermal sink. The circuit components are electrically connected to the IC via flexible electrical interconnects, such as flexible wire bonds. An electrically-insulating coating is deposited upon the flexible electrical interconnects and upon the exposed surfaces of the integrated circuit assembly. A thermally-conductive encapsulating material encases the circuit components and the flexible electrical interconnects within a rigid or semi-rigid matrix.

### SUMMARY

Embodiments of the present invention that are described hereinbelow provide a novel three-dimensional (3D) design approach for electronic integration.

There is therefore provided, in accordance with an embodiment of the present invention, an electronic module, which includes a substrate including a dielectric material having a cavity formed therein. First conductive contacts within the cavity are configured for contact with at least one first electronic component that is mounted in the cavity. Second conductive contacts on a surface of the substrate that surrounds the cavity are configured for contact with at least a second electronic component that is mounted over the cavity. Conductive traces within the substrate are in electrical communication with the first and second conductive contacts.

In a disclosed embodiment, the conductive contacts include first contact pads on the substrate, which are configured to physically and electrically contact second contact pads on a lower surface of the electronic components. Typically, the second electronic component is selected from a group of components consisting of integrated circuit chips and interposers, while the at least one first electronic component is selected from a further group of components consisting of further integrated circuit chips and discrete components.

In some embodiments, the conductive traces include vias, which pass through the substrate in a direction perpendicular to the surface of the substrate that surrounds the cavity. The vias may be laid out on a predefined grid or disposed at a set of predefined angles relative to each of the contacts. Typically, at least one of the vias is configured to connect one of the first conductive contacts with one of the second conductive contacts. Additionally or alternatively, the module includes a plurality of contact pads on an exterior surface of the substrate for contacting a printed circuit board, wherein at least one of the vias is configured to connect one of the conductive contacts with one of the contact pads on the exterior surface.

In some embodiments, the conductive traces include conductive lines, which are disposed in one or more planes parallel to the surface of the substrate that surrounds the cavity. The conductive lines may have a non-uniform thickness. The module may include a plurality of contact pads on a side of the substrate, which is perpendicular to the surface of the substrate that surrounds the cavity, wherein at least one of the conductive lines is configured to connect one of the conductive contacts with one of the contact pads on the side of the substrate. Additionally or alternatively, the conductive lines may include at least first lines, which are disposed in a first plane defined by an inner surface of the cavity, and second lines, which are disposed in a second plane, which contains the surface of the substrate that surrounds the cavity.

In disclosed embodiments, the module includes one or more discrete electronic components embedded in or on an outer surface of the substrate. The discrete electronic components or entire module may be configured and trimmed so as to meet a predefined operational specification. Typically, the components that are embedded in or on the outer surface of the substrate are selected from a group of components consisting of resistors, flat capacitors, interdigital capacitors, and inductors.

In some embodiments, the cavity within which the first conductive contacts are disposed is an inner cavity, and the surface of the substrate that surrounds the inner cavity, on which the second conductive contacts are disposed, is an inner surface, while the substrate has an outer cavity that is configured to contain the at least one second electronic component and is surrounded by an outer surface of the substrate, on which third conductive contacts are disposed, configured for contact with at least a third electronic component that is mounted over the outer cavity.

In alternative embodiments, the cavity is formed in a first side of the substrate, and the substrate is configured for mounting of one or more third electronic components on a second side of the substrate, opposite the first side. In one such embodiment, the cavity formed in the first side of the substrate is a first cavity, and a second cavity is formed in the second side of the substrate and is configured to contain at least one of the third electronic components, which is mounted in the second cavity. The second side of the substrate may be configured for mounting of at least another of the third electronic components over the second cavity.

There is also provided, in accordance with an embodiment of the present invention, an electronic assembly, including at least first and second modules coupled together electrically and mechanically. Each of the modules includes a substrate including a dielectric material having a cavity formed therein. First conductive contacts within the cavity are configured for contact with at least one first electronic component that is mounted in the cavity, while second conductive contacts on a surface of the substrate that surrounds the cavity are configured for contact with at least a second electronic component that is mounted over the cavity. Conductive traces within the substrate are in electrical communication with the first and second conductive contacts.

In a disclosed embodiment, at least the first and second modules include respective contact pads on exterior surfaces of the modules, wherein the contact pads are connected to the conductive traces and are coupled within the assembly to provide electrical communication between at least the first and second modules.

In some embodiments, at least the first module is stacked on the second module in the assembly. The first module may be stacked so that a lower surface of the substrate of the first module, opposite the cavity in the first module, covers and encloses the cavity that is formed in the second module. Alternatively, the first module is stacked so that the cavity in the first module faces into the cavity that is formed in the second module.

Further alternatively, the first module is connected to the second module by contact pads on a side of the first module that is perpendicular to the surface of the substrate of the first module that surrounds the cavity in the first module. In this case, the first module may be oriented so that the cavity in the first module and the cavity in the second module open in respective directions that are mutually parallel or that are mutually perpendicular.

In another embodiment, the assembly includes a dielectric base, wherein at least the first and second modules are mounted side-by-side on a surface of the dielectric base, while the cavity in the first module and the cavity in the second module open in a direction that is perpendicular to the surface.

There is additionally provided, in accordance with an embodiment of the present invention, a method for producing an electronic module. The method includes providing a substrate including a dielectric material having a cavity formed therein, having first conductive contacts within the cavity, second conductive contacts on a surface of the substrate that surrounds the cavity, and conductive traces within the substrate in electrical communication with the first and second conductive contacts. At least one first electronic component is mounted within the cavity in contact with the first conductive contacts. At least a second electronic component is mounted over the cavity, on the surface of the substrate that surrounds the cavity, in contact with the second conductive contacts.

The present invention will be more fully understood from the following detailed description of the embodiments thereof, taken together with the drawings in which:

### BRIEF DESCRIPTION OF THE DRAWINGS

FIG. 1 is a schematic sectional illustration of a multi-level electronic module, in accordance with an embodiment of the present invention;

FIG. 2 is a schematic detail view of a multi-level electronic module, in accordance with an embodiment of the present invention;

FIGS. 3A-3C are schematic top views of successive layers of a multi-level electronic module, in accordance with an embodiment of the present invention;

FIG. 4 is a schematic top view of a layer of a multi-level electronic module, in accordance with an embodiment of the present invention;

FIG. 5 is a schematic detail view of a multi-level electronic module, in accordance with another embodiment of the present invention;

FIGS. 6A-6C are schematic top views of successive layers of a multi-level electronic module, in accordance with an alternative embodiment of the present invention;

FIG. 7 is a schematic top view of a layer of a multi-level electronic module, in accordance with yet another embodiment of the present invention;

FIG. 8 is a schematic sectional illustration of a multi-level electronic module, in accordance with a further embodiment of the present invention;

FIG. 9 is a schematic sectional illustration of a multi-level electronic module, showing laser trimming of an embedded capacitor, in accordance with an embodiment of the present invention;

FIG. 10 is a schematic top view of a layer in a multi-level electronic module, showing an embedded resistor, in accordance with an embodiment of the present invention;

FIG. 11 is a schematic sectional illustration of a multi-level electronic module, showing an embedded flat capacitor, in accordance with an embodiment of the present invention;

FIG. 12 is a schematic sectional illustration of a multi-level electronic module, showing an embedded interdigital capacitor, in accordance with an embodiment of the present invention;

FIG. 13 is a schematic top view of a layer in a multi-level electronic module, showing an embedded inductor, in accordance with an embodiment of the present invention;

FIGS. 14A-C are schematic sectional illustrations of multi-level electronic modules, in accordance with alternative embodiments of the present invention;

FIG. 15 is a schematic sectional illustration of a stack of multi-level electronic modules, in accordance with an embodiment of the present invention;

FIG. 16 is a schematic side view of an assembly comprising multiple multi-level electronic modules, in accordance with an embodiment of the present invention;

FIGS. 17-19 are schematic side views of assemblies comprising multiple multi-level electronic modules, in accordance with alternative embodiments of the present invention; and

FIG. 20 is a schematic side view of an assembly comprising multiple multi-level electronic modules, in accordance with a further embodiment of the present invention.

### DETAILED DESCRIPTION OF EMBODIMENTS

### Overview

Embodiments of the present invention that are described herein provide a new type of electronic module that enables multiple IC chips and other components (including passive discrete components, as well as microelectromechanical, optical and other multifunctional parts) to be mounted together with high component density in a three-dimensional (3D) assembly. Such modules create a platform suitable for components manufactured by different fabrication processes and support incorporation of special materials into 3D designs. This module design also optimizes heat dissipation and thus improves system power capability, while integrated interconnections ensure a high level of reliability. Modules in accordance with embodiments of the present invention are useful in optimizing system performance and reducing product cost and time to market.

In the disclosed embodiments, an electronic module comprises a dielectric substrate having a cavity. (This sort of substrate with one or more cavities is equivalently referred to herein as a “frame.”) Conductive contacts within the cavity permit one or more electronic components, which may be discrete components or ICs, to be mounted on the surface of the substrate within the cavity. Additional conductive contacts on the surface of the substrate that surrounds the cavity can be used to mount one or more additional electronic components, such as an integrated circuit or interposer, over the cavity. The cavity may have two or more nested layers, thus allowing components to be mounted at three or more levels. Discrete components may also be embedded in the substrate itself.

Conductive traces within the substrate connect to the conductive contacts on the surface of the substrate (within and on the surface surrounding the cavity). The traces can be laid out as desired to provide the appropriate connections between the components, as well as to contact pads on the outer surface of the substrate. These outer contact pads can be used to mount the module on a printed circuit board, as well as to connect multiple modules together into a larger assembly.

Embodiments of the present invention implement the following design principles:
Separation of parts with different functions, materials and production processes.
Performance and cost optimization of each part.
Easy assembly of multifunctional parts on 3D dielectric frame.
Minimal number of reliable standard interconnections.
Improved heat dissipation and enhanced reliability.

The dielectric frame that is used in the disclosed embodiments has many advantages, including the following:

1. A wide range of dielectric materials may be used, including, for example, both laminates and ceramics (such as low temperature co-fired ceramic—LTCC).

2. Cost effective manufacturing technologies can be used to produce the frame.

3. The frame has excellent high-frequency properties for use in radio frequency (RF) circuit applications.

4. Existing assembly techniques can be used in assembling components on the frame.

5. The open-cavity design of the frame makes it suitable for use with microelectromechanical systems (MEMS) and optical components, as well as electronic components.

6. Open cavities of different sizes, as shown in the embodiments described below, enable simultaneous mounting of chips from smaller parts on the bottom layers to larger ICs and interposers on the top, without the need for expensive chip embedding to build true 3D multilayer structures with high component density.

7. A ground plane may be formed on the back side of the frame.

8. After component assembly, the frame may optionally be encapsulated, using existing techniques and materials.

9. The flexible design principles enable optimization of module performance by producing each component (including both discrete components and ICs) using the most suitable material and manufacturing techniques. The performance of each part can thus be optimized at an early design stage. Internal, non-inductive connections enable high-speed, low-loss interconnection of components.

10. The frame design supports enhanced reliability. Each part can be pre-tested. The design also allows trimming of the entire assembled module and thus may improve its performance. Heat dissipation can be optimized using the proper interconnections and special materials with high thermal conductivity. ICs with flip-chip or chip-scale form factors can be used for cost-effectiveness and reliability. Modules may be encapsulated, as noted above.

11. As described below, single frames may function as 3D building blocks. These building blocks enable fabrication and assembly of larger, more complicated, multidimensional structures with higher hierarchies.

12. The modularity of these embodiments provide many other benefits in respect to cost, power budget, mechanical stress relief, speed enhancement, and system features such as standardization of testing programs.

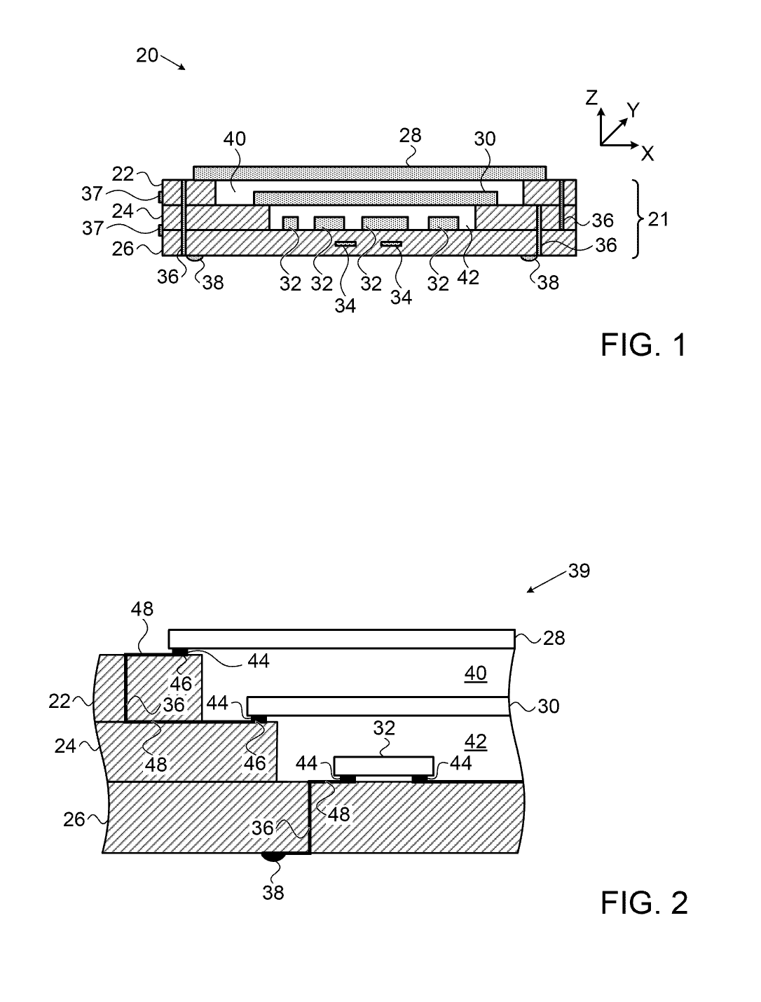

FIG. 1 is a schematic sectional illustration of a multi-level electronic module 20, in accordance with an embodiment of the present invention. The module is built on a dielectric substrate 21, which in this example comprises three layers 22, 24, 26, together defining the frame of module 20. Layers 22 and 24 are open in their centers, thus containing an outer cavity 40 and a nested inner cavity 42. The particular geometry of module 20 is shown by way of example, and modules having alternative geometries are shown in other figures that are described hereinbelow. For convenience, FIG. 1 shows a set of Cartesian axes, with the X- and Y-directions running in the transverse directions parallel to the surfaces of layers 22, 24 and 26 on which components are mounted, while the Z-direction runs perpendicular to these surfaces.

Substrate 21 may comprise any suitable electrically-insulating material. For example, LTCC (ceramic) provides excellent heat transfer and thus facilitates cooling of the components, whereas a laminate is particularly cost-effective in producing multilayer structures. Alternatively, an elastic polymer may be used to provide improved absorption of mechanical vibrations, or other suitable dielectric materials that are known in the art may be chosen depending on system requirements.

Electronic components are mounted in a 3D array in module 20. Components 32 (which may typically be discrete components or ICs) are mounted on the surface of layer 26 within cavity 42. Another component 30, such as an IC, is mounted over cavity 42, on the surface of layer 24 that surrounds the cavity. (Layer 24, and similarly layer 22, may surround the corresponding cavities 42 and 40 on all sides or only on two or three sides.) Yet another component 28, such as an IC or interposer, is mounted over cavity 40, on the surface of layer 22. (Interposers typically comprise simple IC chips with suitable interconnections.) The ICs and discrete components in module 20 may be contained in chip-scale or flip-chip packages or may be assembled as bare dies. Some discrete components 34 can be also embedded in substrate 21, as explained further hereinbelow.

The electronic components mounted on and in module are connected by conductive traces running on and through substrate 21, as shown in the figures that follow. These traces typically include vias 36, which pass through substrate 21 in a direction perpendicular to the surfaces in and surrounding cavities 40 and 42 on which the components are mounted (i.e., in the Z-direction), as well as conductive lines disposed in X-Y planes that are parallel to the component mounting surface, as shown, for example in FIG. 2. The conductive traces and contacts may be produced using standard silver printing or photochemical techniques for copper, or they may, alternative or additionally, comprise other metals, as well as conductive polymers and adhesives.

Module 20 is configured for mounting on a larger underlying substrate, such as a printed circuit board (PCB), using contact pads 37 and/or 38 on the exterior surfaces of substrate 21. Alternatively or additionally, contact pads 37 and/or 38 may be used for connecting module 20 to other modules, as shown, for example, in FIGS. 15-20. External contact pads 37 and 38 may be of any suitable type, such as ball grid array (BGA), land grid array (LGA), or surface mounted device (SMD) contacts. As shown in FIG. 1, contacts 37 are located on the sides of substrate 21 that are perpendicular to the component-mounting surfaces in and surrounding cavities 40 and 42, while contacts 38 are on the bottom surface of the substrate (or the top surface—though this option is not shown in FIG. 1), parallel to the component-mounting surfaces. Typically, contacts 38 are connected to the electronic components in module 20 by vias 36, while contacts 37 are connected by transverse conductive lines running parallel to the component-mounting surfaces, as shown, for example, in FIGS. 4 and 8.

FIG. 2 is a schematic detail view of a multi-level electronic module 39, in accordance with another embodiment of the present invention. This figure shows details of vias 36 and transverse conductive lines 48, as well as their connections to components 28, 30 and 32. Conductive lines 48 typically run, as noted earlier, along the surfaces of layers 22, 24 and 26, and are thus formed both on the inner surface of cavity 42 (on layer 26) and on the surfaces of layers 22 and 24 surrounding cavities 40 and 42. The vias and lines are typically designed for low resistance and little or no inductance.

Vias 36 and lines 48 are connected to the components by conductive contact pads 46 formed on the surfaces of layers 22, 24 and 26 of substrate 21. Contact pads 46 make physical and electrical contact with conductive pads 44 on components 28, 30 and 32, using suitable soldering or other bonding techniques. Thus, these components may be connected the external contact pads (such as pad 38) of module 39, as well as to one another, by means of vias 36 and lines 48 extending between contact pads 46, at either the same or different levels of the substrate.

### Design of Conductive Vias and Lines

Via patterns can be specially designed and produced for each specific module, but the design process can be simplified and production cost reduced by providing standard via patterns for similar packages. For such standard patterns, all available vias may be produced, but only some of them may be connected to components by conductive lines, depending on the electrical scheme of the module.

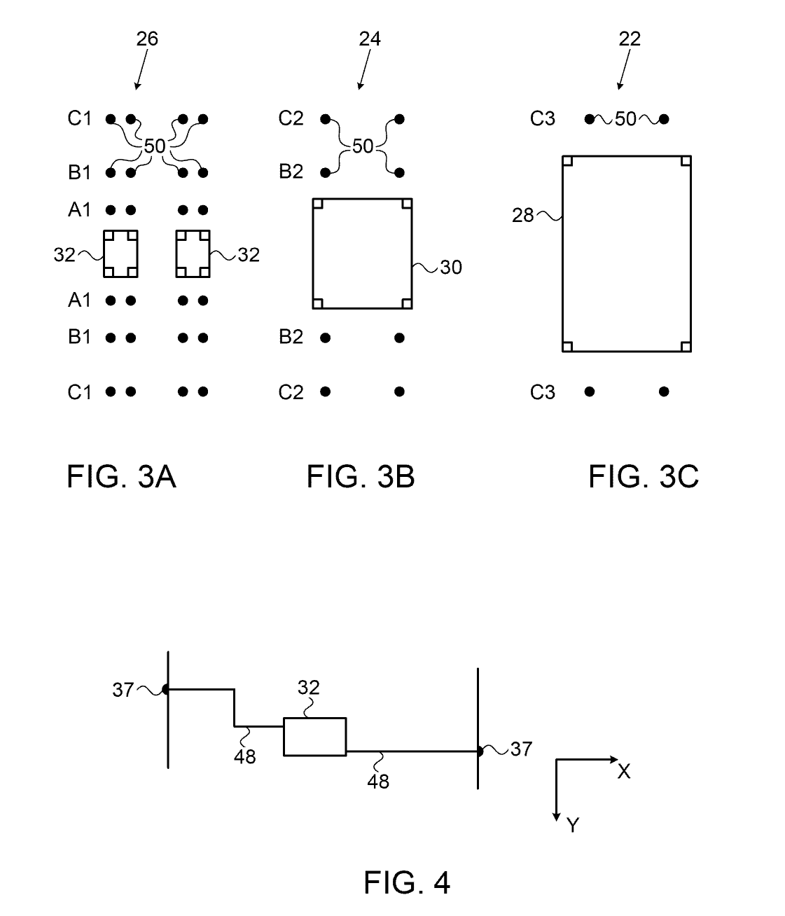

FIGS. 3A-3C are schematic top views of successive layers 26, 24, 22 of a multi-level electronic module, such as module 20, in accordance with an embodiment of the present invention. In this embodiment, vias 50 are laid out in a predefined grid along the X and Y directions. The number of vias that are actually used depends on the number of components, the number of their termination contacts, and the electrical scheme.

In the scheme shown in FIGS. 3A-3C, components 32, 30 and 28 are arranged generally in accordance with their physical sizes (from the smallest to largest in the bottom-to-top direction). The pattern of vias 50 varies from layer to layer accordingly, with the vias marked C (C1, C2 and C3) running through all three layers 22-24-26; the vias marked B running through layers 24 and 26; and the vias marked A running only through layer 26, between the surface on which components 32 are mounted and the lower surface, where pads 38 are located. Thus, depending on the layout of transverse conductors 48 (not shown in these figures), the “C” vias may interconnect components on any of the layers or connect these components to external contact pads. The “B” and “A” vias are more limited in their connectivity, but together the grid of vias available in the pictured module can be used to provide substantially any desired pattern of inter-component and external connections.

FIG. 4 is a schematic top view of a layer of a multi-level electronic module, showing transverse conductive lines 48 in accordance with an embodiment of the present invention. Lines 48 are laid out in a rectilinear pattern, like vias 50 in FIGS. 3A-3C. In the example shown in FIG. 4, lines 48 connect component 32 to contact pads 37 on the sides of the module. Alternatively, the same sorts of lines may be connected to vias, as well as to other components in the same layer.

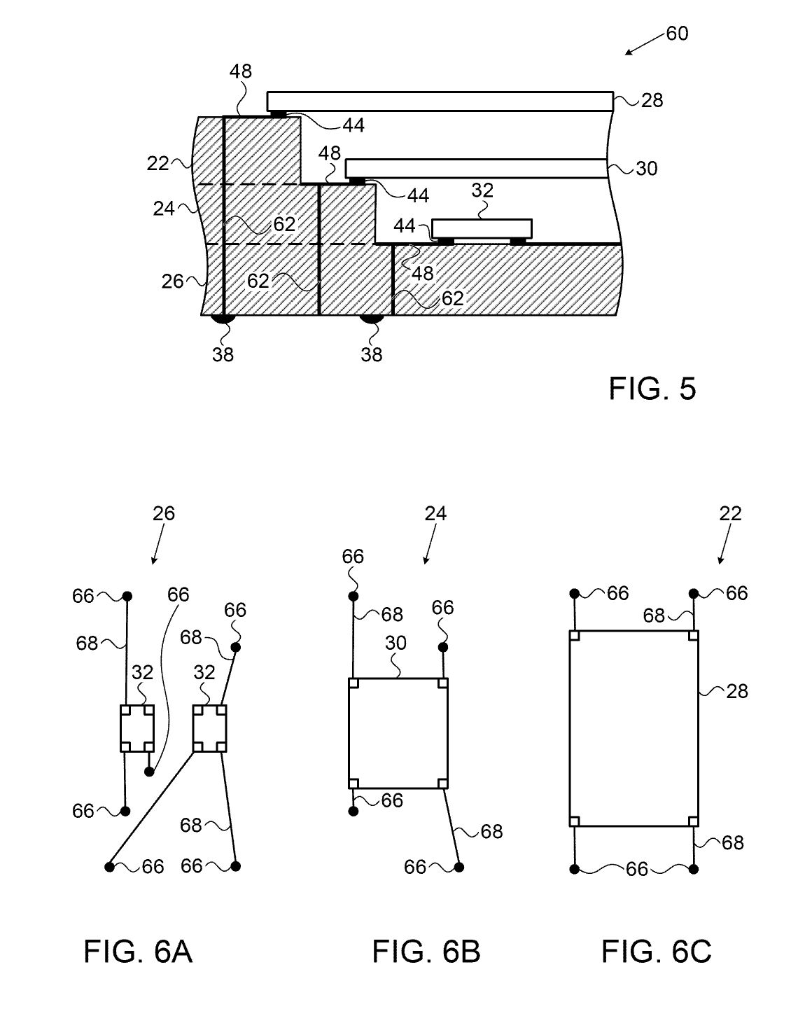

FIG. 5 is a schematic detail view of a multi-level electronic module 60, in accordance with another embodiment of the present invention. This figure shows how transverse lines 48 and vias 62 may be used to connect components 28, 30, 32 to contact pads 38 on the lower surface of layer 26 of the substrate. The same sorts of lines and vias may be used in the scheme shown in FIG. 2 and in substantially any other sort of interconnection scenario.

FIGS. 6A-6C are schematic top views of successive layers 26, 24, 22 of a multi-level electronic module, in accordance with an alternative embodiment of the present invention. Unlike the preceding embodiment, this design is not based on a fixed array of vias, but rather uses only specific vias 66 passing through the appropriate layers at the required locations, along with transverse lines 68 connecting these vias to components 28, 30 and 32. This approach may use less metal and offer greater design flexibility, with the possibility of tighter packing of components in the module in some applications.

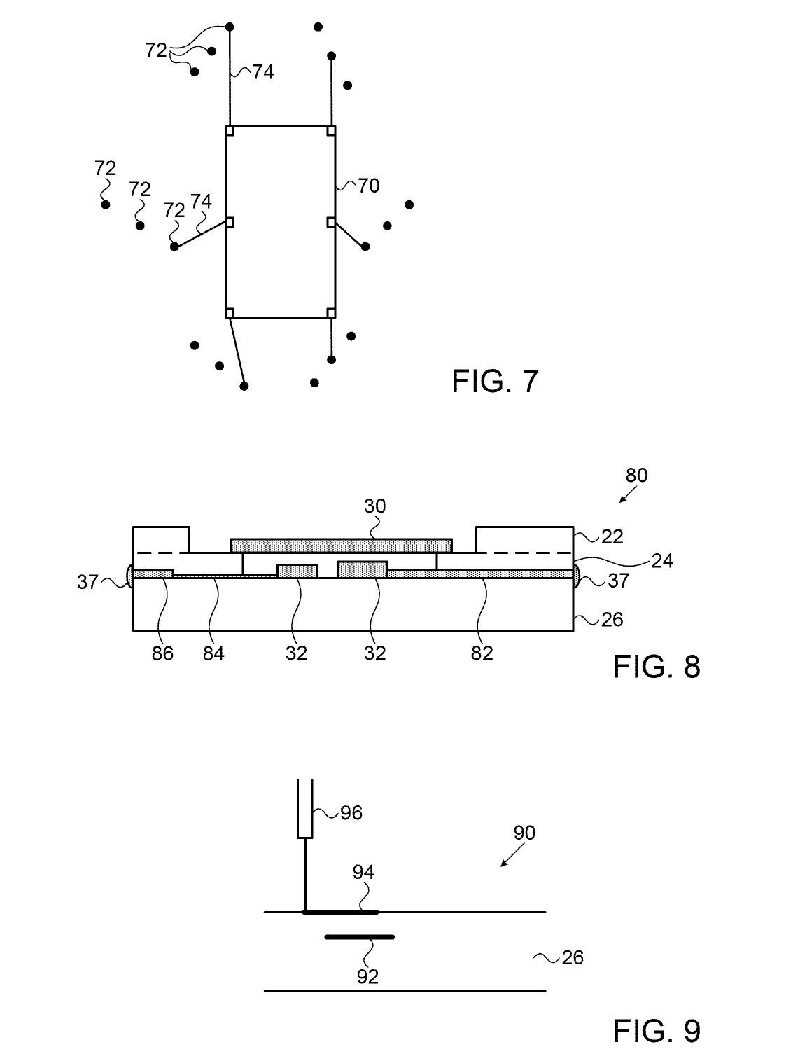

FIG. 7 is a schematic top view of a layer of a multi-level electronic module, in accordance with yet another embodiment of the present invention. In this embodiment, vias 72 are disposed at a set of predefined angles relative to the contacts on which a component 70 is mounted. Transverse conductive lines 74 are then formed between the component contacts and the vias that are actually in use. This sort of design approach may offer a useful compromise between the grid-based design shown in FIGS. 3A-3C and the “free-form” design of FIGS. 6A-6C.

Regardless of the sort of layout that is chosen, drilling and metal plating are typically the most suitable techniques for producing vertical vias in laminated substrates. The drilling can be performed mechanically or by laser, followed by copper plating using methods that are known in the art. Reliable, non-inductive contact can generally be achieved in this manner with via diameters in the range of 50-350 microns (although larger and smaller vias are also possible).

For ceramic substrates, thick-film techniques are typically the most suitable. In this case, openings for vias are mechanically prepared in each layer of the ceramic green tape that is used in producing the substrate. Screen printing of silver, palladium-silver, or other metal paste is used to fill these openings with conductive material. A multilayer structure made of the ceramic green tape is then pressed together and sintered. In order to connect components with side terminations, thick conductive lines (traces) can be used instead of or together with vias.

FIG. 8 is a schematic sectional illustration of a multi-level electronic module 80, showing transverse conductive lines 82, 84, in accordance with a further embodiment of the present invention. As illustrated in this figure, in order to connect components 32 with exterior contact pads 37, thick metal traces may be used instead of or together with drilling of vias. Traces of this sort may also be used to create horizontal fragments connecting to vertical vias.

For laminated substrates, thick metal cladding (generally in the range of 150-600 microns, although larger and smaller thicknesses may alternatively be used) is typically the most suitable technique for producing traces 82, 84. Metal traces up to 250 mils thick in copper and up to 500 mils in aluminum can be produced using cladding techniques that are known in the art. Such a thickness is more than enough to produce reliable and non-inductive traces in the thickness range defined above. Various techniques can be used in patterning of the thick metal (for laminate frames), such as photochemical, micro-mechanical, and laser-based techniques, as are known in the art.

Transverse conductive lines 82, 84 may be of uniform or non-uniform thickness. For example, the termination of transverse line 84 at side contact 37 may include a thick part 86 close to contact 37. This thicker part may improve termination contact for traces with thickness up to 250 microns. This sort of variable trace thickness may also be useful for transverse connections of vertical vias. A minimal metal thickness may be used elsewhere to provide reliable and non-inductive contact, easy manufacturing of multilayer structures, and cost-effective metal patterning.

To summarize, the sequence of steps in producing a 3D module as described above with a laminated substrate may include the following:
1. Preparation of individual layers (cavities included).
2. Metal patterning for each layer in order to give the required pattern of lines and contact pads.
3. Lamination.
4. Drilling and plating of vertical vias.
5. Addition of external terminations.
6. Assembly of components.

For ceramic substrates, thick metal traces (connecting to side contacts or vias) can be built by multi-screen printing of conductive thick-film paste, which simultaneously allows patterning of the trace. In this sort of module, trace thickness in the range of 150-250 microns is typically desirable.

To summarize in this case, for ceramic technology, the sequence of steps in production of a 3D module may be as follows:
1. Preparation of green ceramic tape for every layer (with required cavities and vias)—including screen printing of lines, vias and contact pads for every layer.
2. Pressing the individual layers together to form a multilayer structure.
3. Sintering.
4. Addition of external terminations.
5. Assembly of components.

New 3D printing (additive manufacturing) techniques are also suitable for frame production. In this case, the 3D frame is just printed layer by layer with the desired combination of conductive materials for pads, lines and vias, and insulating material for the rest. This manufacturing technique is cost-effective for thick conductive horizontal traces and vertical vias in complicated patterns.

### Incorporation of Embedded Components

As illustrated schematically in FIG. 1, substrate 21 may contain embedded components 34, such as resistors, capacitors and inductors. Such components may be used in substantially any type of electronic module, but they are particularly useful in construction of various types of RF circuits and chips, such as filters, baluns and transformers. The embedded components may be used in conjunction with other discrete components placed on the mounting surfaces of the substrate, such as components 32 (FIG. 1). This combination enables the construction of more complicated sorts of RF (and other) modules, such as filters and multiplexers.

Additional techniques may be used to enhance and refine the properties of embedded components 34. For example, trimming techniques, such as laser trimming, may be used to fine-tune the component values in production. Additionally or alternatively, special materials, such as ferrites and ferroelectrics, may be incorporated in the components that are embedded in or on the outer surface the substrate for improved performance. These options are illustrated in the figures that follow. A number of specific components are described below, but the principles of trimming provided by the present embodiments can be applied to substantially any sort of trimmable component that can be embedded in or on the substrate in this manner.

FIG. 9 is a schematic sectional illustration of a multi-level electronic module, showing laser trimming of an embedded capacitor 90, in accordance with an embodiment of the present invention. Dielectric layer 26 in this embodiment is itself a multi-layer structure. Thus, capacitor 90 comprises an inner conductive plate 92, formed on an inner layer surface of layer 26, and an outer conductive plate 94, formed on the upper surface of layer 26 to enable trimming. The characteristics of capacitor 90 are measured, and a laser 96 removes sufficient material from plate 94 to reach the appropriate component values to give the desired operating properties at the design frequency of the module. For example, in producing filters and multiplexers, insertion loss and rejection in specified frequency bands is measured, and electromagnetic simulation is applied (as is known in the art) to calculate the required trimming values. Similar techniques may be used in modules of other types.

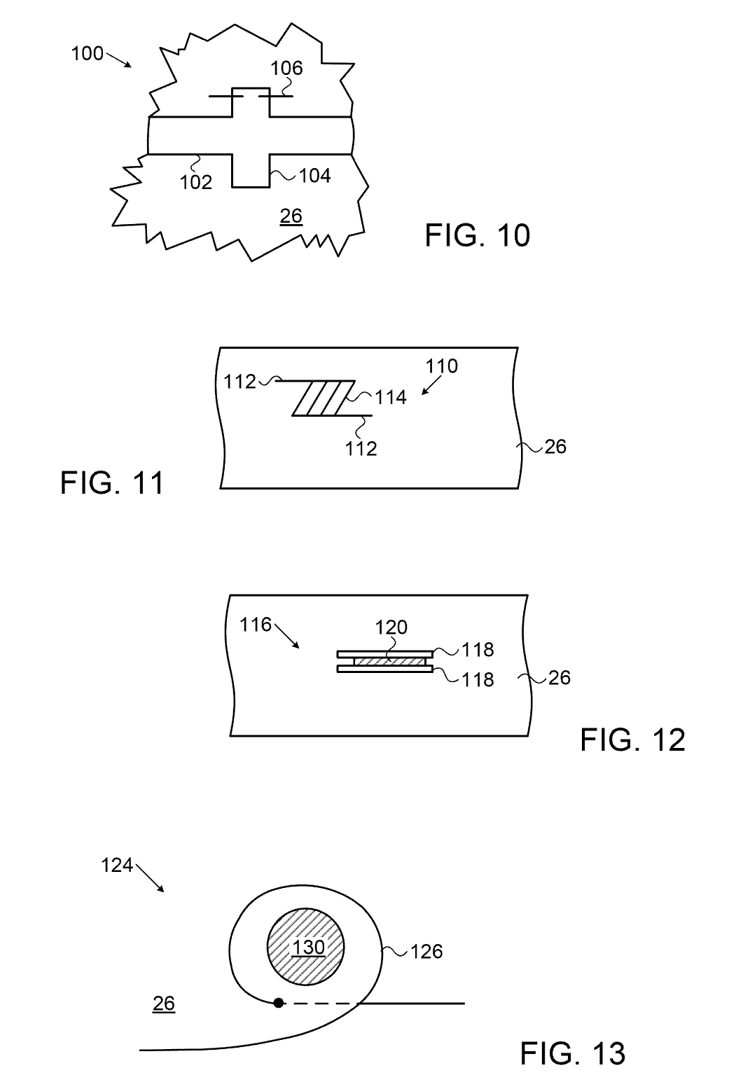

FIG. 10 is a schematic top view of a layer in a multi-level electronic module, showing an embedded resistor 100 in accordance with an embodiment of the present invention. Resistor 100 comprises a conductive trace 102, which connects to a resistive pad 104. The resistance of resistor 100 is determined by the width of pad. Thus, the resistance may be trimmed, using the techniques described above, by cutting pad 104, for example along a line 106.

Similarly, resistors, inductors and interdigital capacitors may be formed on the outer surface of one of the layers of a module, and then trimmed by similar techniques. For example, resistance and inductance values may be trimmed by narrowing the conductive lines, while capacitance is trimmed by removing a part of the electrodes. This approach allows testing and trimming of the entire module, either before or after the components of the module have been assembled. Such modules can be individually tested and trimmed in highly-standardized test programs by automatic equipment.

Alternatively or additionally, when trimming is not required, embedded components 34 may be contained entirely within one of the dielectric layers of the substrate, along with suitable conductive traces connecting to them. Circuit corrections may still be achieved, for example, by means of discrete components 32 mounted on the frame.

Various techniques may be used to embed components 32 in a layer of a module substrate (and in other layers within the dielectric frame of a module, whether or not the component surfaces are to be available for subsequent trimming). When the substrate comprises a laminate, the conductors and other elements making up the component (such as ferroelectric and/or magnetic elements) may simply be embedded at the appropriate stages in the process of lamination. On the other hand, ceramic substrates generally require high-temperature sintering, which can damage embedded components. Therefore, when a ceramic substrate is used, holes may be left in the substrate at the sintering stage for insertion of embedded components thereafter. After the components have been inserted, the holes may optionally be filled with a suitable encapsulation material.

FIG. 11 is a schematic sectional illustration of a multi-level electronic module, showing an embedded flat capacitor 110, in accordance with an embodiment of the present invention. A ferroelectric material 114 is embedded in substrate layer 26 between electrodes 112 of the capacitor.

FIG. 12 is a schematic sectional illustration of a multi-level electronic module, showing an embedded interdigital capacitor 116, in accordance with another embodiment of the present invention. In this case, a set of interleaved electrodes 120 of the capacitor may be embedded alongside or between one or more embedded ferroelectric layers 118.

FIG. 13 is a schematic top view of a layer in a multi-level electronic module, showing an embedded inductor 124, in accordance with still another embodiment of the present invention. Here a ferrite 130 or other magnetic material is embedded in layer 26 within a wire coil 126 of the inductor in order to increase inductance.

### Alternative Frame Designs and Multi-Frame Modules

The frame geometry of module 20 that is shown in FIG. 1 and is repeated in a number of the subsequent figures is representative of the sort of structures that may be created based on the principles of the present invention, but it is shown only by way of example and not limitation. A number of further examples are shown in the figures that follow. Alternative cavity-based, multi-level module designs will be apparent to those skilled in the art after reading the present description and are considered to be within the scope of the present invention.

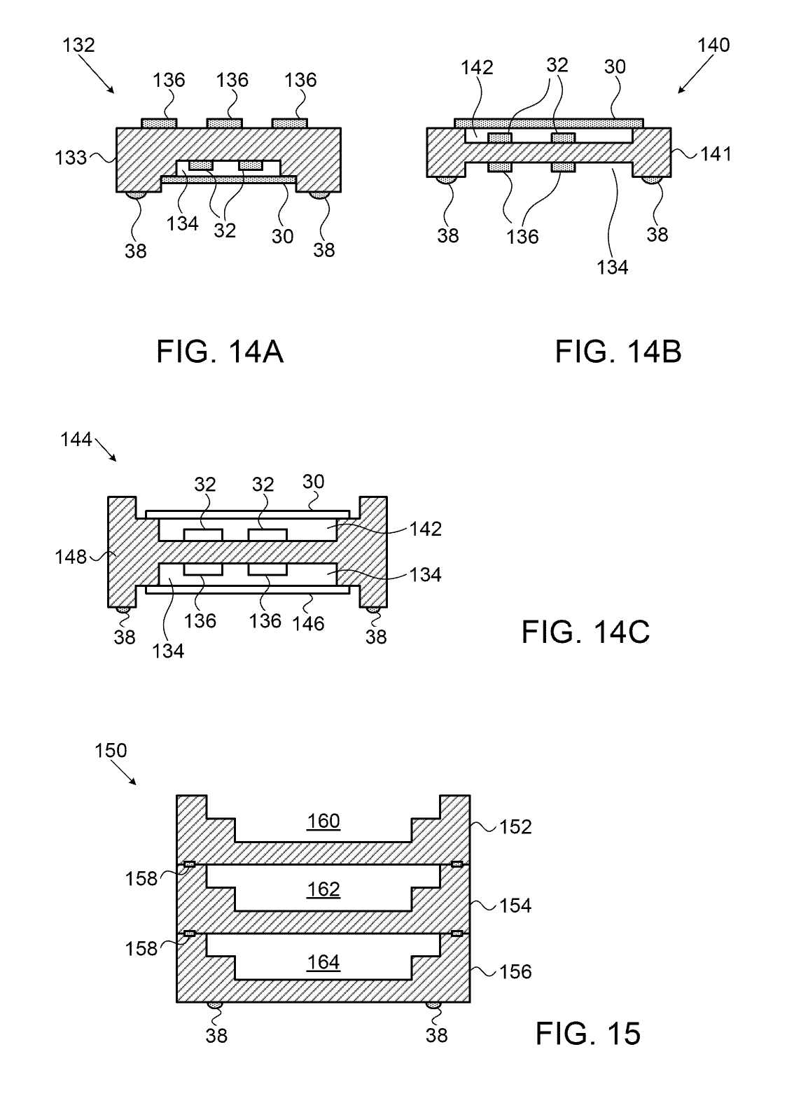

FIG. 14A is a schematic sectional illustration of a multi-level electronic module 132, in accordance with an alternative embodiment of the present invention. Here a cavity 134 is formed in one side of the substrate, and components 30 and 32 are mounted over and in the cavity, respectively. Additional traces (not shown) are provided on the other side of the substrate of module 132, opposite cavity 134, to enable mounting of further components 136 on this opposite side, as well. In this embodiment, contact pads 38 are formed on the same side of the substrate as cavity 134 (rather than on the opposite side as in the preceding embodiments), and thus enable module 132 to be mounted on a PCB or other underlying substrate with the cavity facing toward the substrate.

FIG. 14B is a schematic sectional illustration of a multi-level electronic module 140, in accordance with another embodiment of the present invention. In this case, the substrate has cavities 134 and 142 formed on both sides and has contact pads 38 alongside cavity 134. Components 136 are mounted in cavity 134, while components 30 and 32 are mounted over and in cavity 142.

FIG. 14C is a schematic sectional illustration of a multi-level electronic module 144, in accordance with yet another embodiment of the present invention. This embodiment is similar to module 140, but also provides mounting surfaces around the edges of both cavity 134 and cavity 142, so that components 146 and 30 may be mounted over these cavities respectively.

Although the preceding figures all show modules comprising only a single substrate frame, in the embodiments described below two or more of these modules may be coupled together electrically and mechanically to produce a single, integrated electronic assembly. This coupling is typically accomplished by joining together suitable contact pads on the exterior surfaces of the modules. For example, flip-chip terminations on any side of the substrates may be used for this purpose. This approach enables incorporation of single modules into complicated 3D structures and arrays by soldering or bonding the frames to each other. It can be useful not only for electronic circuits, but also for optical and electro-mechanical devices, as well as some types of “system in package” products.

FIG. 15 is a schematic sectional illustration of an assembly 150 of this sort, in accordance with an embodiment of the present invention. Assembly 150 comprises a stack of multi-level electronic modules, 152, 154, 156. These modules typically contain internal conductive contacts and traces similar to those shown in the preceding figures. Modules 152, 154 and 156 are connected to one another by contact pads 158 on their respective upper and/or lower surfaces, which connect to the traces within each module and thus provide electrical communication between the modules.

Modules 152, 154 and 156 contain respective cavities 160, 162 and 164. The modules are stacked in this embodiment so that the lower surface of the substrate in module 152 (opposite cavity 160) covers and encloses cavity 162 in module 154, while the lower surface of the substrate in module 154 covers and encloses cavity 164 in module 156.

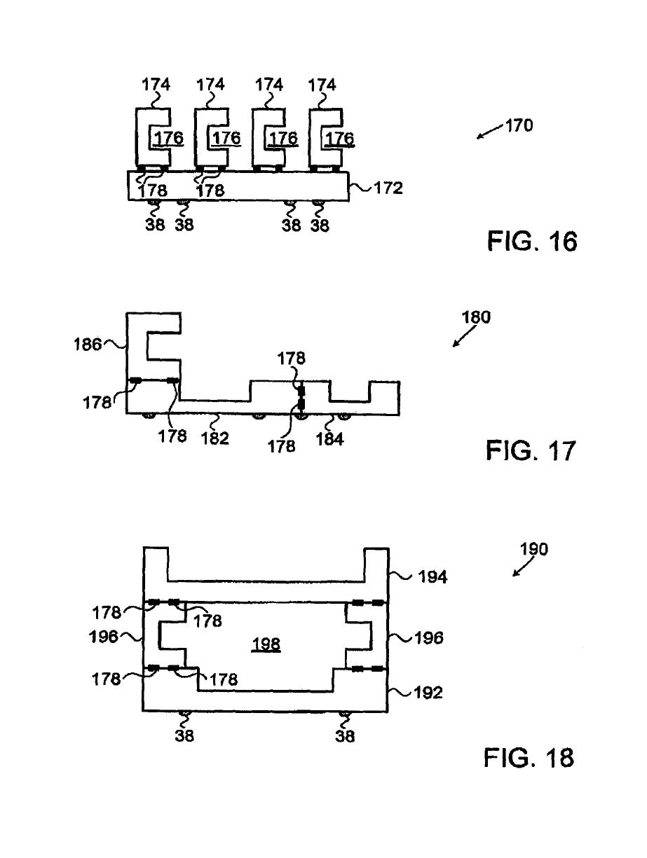

FIG. 16 is a schematic side view of an assembly 170 comprising multiple multi-level electronic modules 174, in accordance with another embodiment of the present invention. In this embodiment, each module 174 contains a respective cavity 176 and has contact pads 178 on a side of the module that is perpendicular to the surface of the module substrate that surrounds the cavity. Modules 174 are thus mounted side-by-side on the upper surface of a dielectric base 172, with their cavities 176 opening in a direction perpendicular to the surface. Base 172 may itself be mounted on a PCB or other substrate by means of contact pads 38. This configuration is particularly useful in creating multi-module assemblies with high component density.

FIG. 17 is a schematic side view of an assembly 180 comprising multiple multi-level electronic modules 182, 184, 186, in accordance with an alternative embodiment of the present invention. Each of modules 182, 184, 186 is attached to at least one of the other modules by contact pads 178 formed on a side of the module that is perpendicular to the surface of the module substrate that surrounds its respective cavity. This arrangement allows modules 182 and 184 to be connected together in an orientation such that their respective cavities open in mutually-parallel directions. On the other hand, contact pads on the upper surface of module 182 enable module 186 to be mounted, as shown in the figure, with its cavity opening in a direction perpendicular to that of the cavities in modules 182 and 184.

This flexibility in placement of the contact pads, for mutual attachment of the modules, allows assemblies to be created in a wide variety of shapes and configurations.

FIG. 18, for example, is a schematic side view of an assembly 190 comprising multiple multi-level electronic modules 192, 194 and 196, in accordance with an alternative embodiment of the present invention. In this case, modules 196 are mounted vertically between modules 192 and 194, using contact pads 178 on the sides of modules 196 and on the top and bottom of modules 192 and 194, respectively. This arrangement defines a central cavity 198 that is enclosed by the modules.

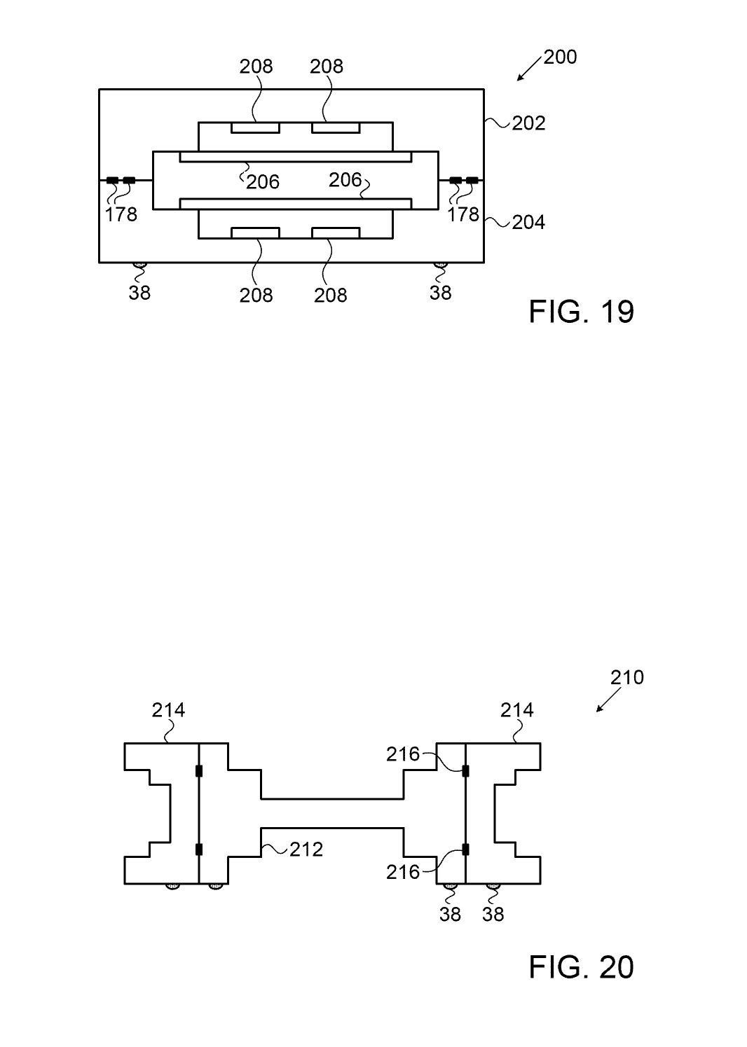

FIG. 19 is a schematic side view of an assembly 200 comprising two multi-level electronic modules 202 and 204, in accordance with yet another embodiment of the present invention. In this case, modules 202 and 204 are stacked so that the cavity in module 202 faces into the corresponding cavity in module 204. Components 206 are mounted over the respective inner cavities of modules 202 and 204, while components 208 are mounted within the inner cavities. The modules are joined together by contact pads on their respective upper surfaces. This embodiment can thus use a single module design, of the type described above, to achieve roughly twice the component density relative to the “real estate” consumed on the PCB on which the assembly is mounted.

FIG. 20 is a schematic side view of an assembly 210 comprising multiple multi-level electronic modules 212 and 214, in accordance with a further embodiment of the present invention. Module 212 is of a type similar to that shown in FIG. 14C, with upper and lower cavities. Modules 214 have a geometry similar to that of module 20 (FIG. 1), and are connected in a perpendicular configuration, to the sides of module 212, by contact pads 216.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An electronic module, comprising:
a substrate comprising a dielectric material having a cavity formed therein;
first conductive contacts within the cavity, configured for contact with at least one first electronic component that is mounted in the cavity;
second conductive contacts on a surface of the substrate that surrounds the cavity, configured for contact with at least a second electronic component that is mounted over the cavity; and
conductive traces within the substrate in electrical communication with the first and second conductive contacts.

2-11. (canceled)

12. The module according to claim 1, wherein the conductive traces comprise conductive lines, which are disposed in one or more planes parallel to the surface of the substrate that surrounds the cavity, and comprising a plurality of contact pads on a side of the substrate, which is perpendicular to the surface of the substrate that surrounds the cavity, wherein at least one of the conductive lines is configured to connect one of the conductive contacts with one of the contact pads on the side of the substrate.

13. (canceled)

14. The module according to claim 1, and comprising one or more discrete electronic components embedded in or on an outer surface of the substrate.

15. The module according to claim 14, wherein the discrete electronic components are configured and trimmed so that the components or the entire module meet a predefined operational specification.

16. (canceled)

17. The module according to claim 1, wherein the cavity within which the first conductive contacts are disposed is an inner cavity, and wherein the surface of the substrate that surrounds the inner cavity, on which the second conductive contacts are disposed, is an inner surface, and
wherein the substrate has an outer cavity that is configured to contain the at least one second electronic component and is surrounded by an outer surface of the substrate, on which third conductive contacts are disposed, configured for contact with at least a third electronic component that is mounted over the outer cavity.

18. The module according to claim 1, wherein the cavity is formed in a first side of the substrate, and wherein the substrate is configured for mounting of one or more third electronic components on a second side of the substrate, opposite the first side.

19. The module according to claim 18, wherein the cavity formed in the first side of the substrate is a first cavity, and wherein a second cavity is formed in the second side of the substrate and is configured to contain at least one of the third electronic components, which is mounted in the second cavity.

20. The module according to claim 19, wherein the second side of the substrate is configured for mounting of at least another of the third electronic components over the second cavity.

21. An electronic assembly, comprising at least first and second modules coupled together electrically and mechanically, each of the modules comprising:
a substrate comprising a dielectric material having a cavity formed therein;
first conductive contacts within the cavity, configured for contact with at least one first electronic component that is mounted in the cavity;
second conductive contacts on a surface of the substrate that surrounds the cavity, configured for contact with at least a second electronic component that is mounted over the cavity; and
conductive traces within the substrate in electrical communication with the first and second conductive contacts.

22. The assembly according to claim 21, wherein at least the first and second modules comprise respective contact pads on exterior surfaces of the modules, wherein the contact pads are connected to the conductive traces and are coupled within the assembly to provide electrical communication between at least the first and second modules.

23. The assembly according to claim 21, wherein at least the first module is stacked on the second module in the assembly.

24. The assembly according to claim 23, wherein the first module is stacked so that a lower surface of the substrate of the first module, opposite the cavity in the first module, covers and encloses the cavity that is formed in the second module.

25. The assembly according to claim 23, wherein the first module is stacked so that the cavity in the first module faces into the cavity that is formed in the second module.

26. The assembly according to claim 23, wherein the first module is connected to the second module by contact pads on a side of the first module that is perpendicular to the surface of the substrate of the first module that surrounds the cavity in the first module.

27. The assembly according to claim 26, wherein the first module is oriented so that the cavity in the first module and the cavity in the second module open in respective directions that are mutually parallel.

28. The assembly according to claim 26, wherein the first module is oriented so that the cavity in the first module and the cavity in the second module open in respective directions that are mutually perpendicular.

29. The assembly according to claim 21, and comprising a dielectric base, wherein at least the first and second modules are mounted side-by-side on a surface of the dielectric base, while the cavity in the first module and the cavity in the second module open in a direction that is perpendicular to the surface.

30. A method for producing an electronic module, the method comprising:
providing a substrate comprising a dielectric material having a cavity formed therein, having first conductive contacts within the cavity, second conductive contacts on a surface of the substrate that surrounds the cavity, and conductive traces within the substrate in electrical communication with the first and second conductive contacts;
mounting at least one first electronic component within the cavity in contact with the first conductive contacts; and
mounting at least a second electronic component over the cavity, on the surface of the substrate that surrounds the cavity, in contact with the second conductive contacts.

31-43. (canceled)

44. The method according to claim 30, wherein providing the substrate comprises embedding one or more discrete electronic components in or on an outer surface of the substrate, and wherein embedding the one or more discrete electronic components comprises trimming at least one of the embedded components so that the components or the entire module meet a predefined operational specification.

45-49. (canceled)

50. A method for producing an electronic assembly, comprising coupling together, electrically and mechanically, at least first and second modules produced according to the method of claim 30.

51-58. (canceled)
